(19) United States
(12) Patent Application Publication
(10) Pub. No.: US 2025/0292811 A1
(43) Pub. Date: Sep. 18, 2025

(54) MEMORY DEVICE

(71) Applicant: Kioxia Corporation, Minato-ku (JP)

(72) Inventor: Kosuke HATSUDA, Tokyo (JP)

(73) Assignee: Kioxia Corporation, Minato-ku (JP)

(21) Appl. No.: 18/830,199

(22) Filed: Sep. 10, 2024

(30) Foreign Application Priority Data
Mar. 13, 2024 (JP) 2024-038913

(51) Int. Cl. G11C 5/08; G11C 11/16; H10B 61/00; H10N 50/10

(52) U.S. Cl. CPC G11C 5/08; G11C 11/161; G11C 11/1673; H10B 61/22; H10N 50/10

(57) ABSTRACT

A memory cell includes a first terminal and a second terminal. A first interconnect is coupled to the first terminal. A second interconnect is coupled to the second terminal. A first switch is coupled between the second interconnect and a third interconnect configured to be coupled to a first voltage. A current mirror circuit includes a third terminal and a fourth terminal, is coupled to the first interconnect at the third terminal, and is configured to output an output current using a first current flowing through the first interconnect as a reference current at the fourth terminal. A sense amplifier circuit is coupled to the fourth terminal.

### CROSS-REFERENCE TO RELATED APPLICATION(S)

This application is based upon and claims the benefit of priority from Japanese Patent Application No. 2024-038913, filed Mar. 13, 2024, the entire contents of which are incorporated herein by reference.

### FIELD

Embodiments described herein relate generally to a memory device.

### BACKGROUND

Examples of a memory device include a magnetic memory device. The magnetic memory device stores data using a magnetoresistance effect.

### BRIEF DESCRIPTION OF THE DRAWINGS

FIG. 1 illustrates functional blocks of a memory device of a first embodiment.

FIG. 2 is a circuit diagram of a memory cell array of the memory device of the first embodiment.

FIG. 3 is a perspective view of a part of the memory cell array of the memory device of the first embodiment.

FIG. 4 illustrates a cross section of an example of a structure of a memory cell of the memory device of the first embodiment.

FIG. 5 illustrates an example of a curve of voltage and current characteristics of the memory cell of the memory device of the first embodiment.

FIG. 6 illustrates an example of components and coupling of the components of a read circuit of the memory device of the first embodiment.

FIG. 7 illustrates states of several signals during data reading of the memory device of the first embodiment along time.

FIG. 8 illustrates an example of the components and coupling of the components of a read circuit of a reference memory device.

FIG. 9 illustrates components of a memory device and coupling of the components of a modification of the first embodiment.

### DETAILED DESCRIPTION

In general, according to one embodiment, a memory device includes a memory cell, a first interconnect, a second interconnect, a first switch, a current mirror circuit, and a sense amplifier circuit. The memory cell includes a first terminal and a second terminal. The first interconnect is coupled to the first terminal. The second interconnect is coupled to the second terminal. The first switch is coupled between the second interconnect and a third interconnect configured to be coupled to a first voltage. The current mirror circuit includes a third terminal and a fourth terminal, is coupled to the first interconnect at the third terminal, and is configured to output an output current using a first current flowing through the first interconnect as a reference current at the fourth terminal. The sense amplifier circuit is coupled to the fourth terminal.

Embodiments will now be described with reference to the figures. In order to distinguish components having substantially the same function and configuration in an embodiment or over different embodiments from each other, an additional numeral or letter may be added to the end of each reference numeral or letter.

The specification and the claims, when mentioning that a particular (first) component is “coupled” to another (second) component, intend to cover both the form of the first component directly coupled to the second component and the form of the first component coupled to the second component via one or more components which are always or selectively conductive.

### 1. First Embodiment

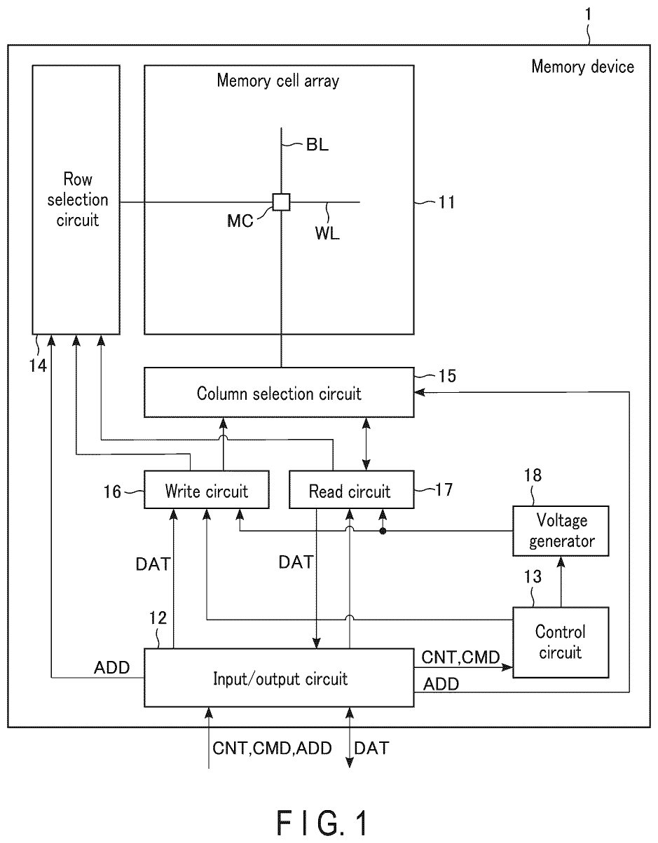

FIG. 1 illustrates functional blocks of a memory device of a first embodiment. A memory device 1 is a magnetic memory device and stores data using a layer stack of magnetic bodies exhibiting dynamically variable resistance. As illustrated in FIG. 1, the memory device 1 includes a memory cell array 11, an input/output circuit 12, a control circuit 13, a row selection circuit 14, a column selection circuit 15, a write circuit 16, a read circuit 17, and a voltage generator 18.

The memory cell array 11 is a set of arrayed memory cells MC. The memory cells MC can store data in a nonvolatile manner. A plurality of first type interconnects and a plurality of second type interconnects are located in the memory cell array 11. In the following description, one of the first type interconnect and the second type interconnect is referred to as word line WL and the other is referred to as bit line BL. The following description is based on an example in which the word line WL is associated with a row and the bit line BL is associated with a column. Each memory cell MC is coupled to one word line WL and one bit line BL. One memory cell MC is selected by selection of one row and selection of one column.

The input/output circuit 12 is a circuit that inputs and outputs data and signals. The input/output circuit 12 receives a control signal CNT, a command CMD, address information ADD, and data DAT from the outside of the memory device 1, for example, from a memory controller. The input/output circuit 12 outputs the data DAT.

The voltage generator 18 is a circuit that generates voltages of various magnitudes from voltages received from the outside of the memory device 1. The voltage generator 18 outputs one or more voltages of constant magnitude used for data reading. The voltage generator 18 outputs a voltage of constant magnitude and a voltage of dynamically variable magnitude used for data writing.

The write circuit 16 is a circuit that controls writing of data in the memory cell MC. The write circuit 16 receives the write data DAT from the input/output circuit 12 and receives (or, is coupled to) the voltage for data writing from the voltage generator 18. The write circuit 16 outputs, based on control of the control circuit 13 and the write data DAT, a voltage and a current used for data writing.

The read circuit 17 is a circuit that controls reading of data from the memory cell MC. The read circuit 17 receives the voltage used for the data reading from the voltage generator 18. The read circuit 17 determines data stored in the memory cell MC using the voltage used for the data reading based on the control of the control circuit 13. The read circuit 17 includes a plurality of sense amplifier circuits SAC (not shown).

The row selection circuit 14 is a circuit that selects a row of the memory cell MC. The row selection circuit 14 receives the address information ADD from the input/output circuit 12. The row selection circuit 14 receives the voltage for data writing from the write circuit 16. The row selection circuit 14 receives the voltage for reading data from the read circuit 17. The row selection circuit 14 uses the voltage for data writing during data writing to select one or more word lines WL associated with a row specified by the received address information ADD. During data reading, the row selection circuit 14 uses the voltage for data reading to select one or more word lines WL associated with the row specified by the received address information ADD.

The column selection circuit 15 is a circuit that selects a column of the memory cell MC. The column selection circuit 15 receives the address information ADD from the input/output circuit 12. The column selection circuit 15 receives the voltage for data writing from the write circuit 16. The column selection circuit 15 receives the voltage for data reading from the read circuit 17. During data writing, the column selection circuit 15 uses the voltage for data writing to select one or more bit lines BL associated with a column specified by the received address information ADD. During data reading, the column selection circuit 15 uses the voltage for data reading to select the one or more bit lines BL associated with the column specified by the received address information ADD.

The control circuit 13 is a circuit that controls the operation of the memory device 1. The control circuit 13 receives the control signal CNT and the command CMD from the input/output circuit 12. The control circuit 13 controls the write circuit 16 and the read circuit 17 based on control instructed by the control signal CNT and the command CMD. Specifically, the control circuit 13 controls the write circuit 16 to supply the voltage received by the write circuit 16 from the voltage generator 18 to the row selection circuit 14 and the column selection circuit 15 during writing of data in the memory cell MC. The control circuit 13 controls the read circuit 17 to supply the voltage received by the read circuit 17 from the voltage generator 18 to the row selection circuit 14 and the column selection circuit 15 during reading of data from the memory cell MC.

### 1.1.2. Circuit Configuration of Memory Cell Array

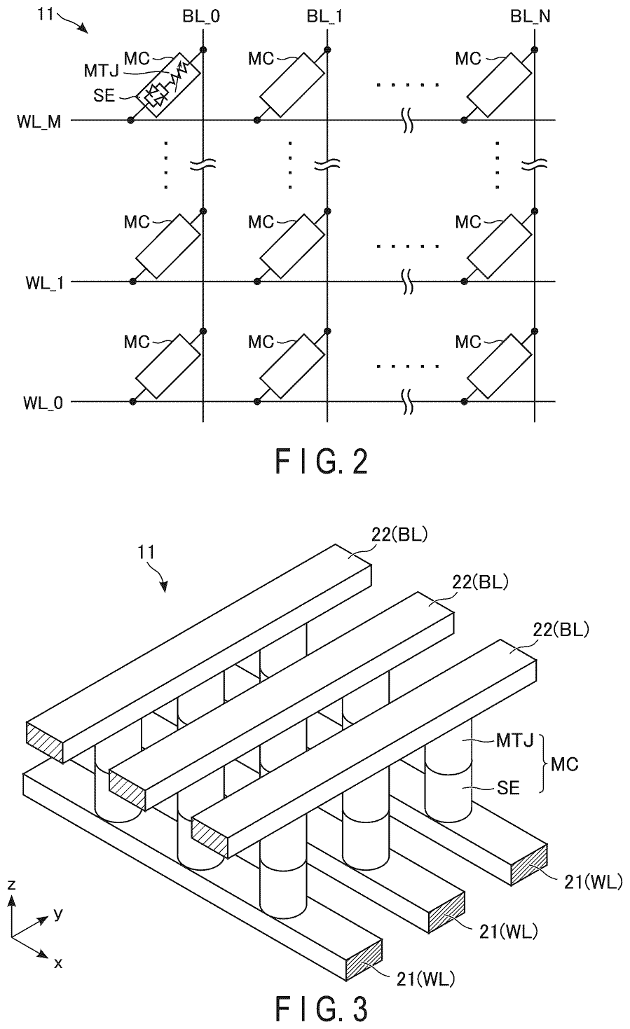

FIG. 2 is a circuit diagram of a memory cell array of the memory device of the first embodiment. As illustrated in FIG. 2, M+1 word lines WL (i.e., WL_0, WL_1, . . . , and WL_M) and N+1 bit lines BL (i.e., BL_0, BL_1, . . . , and BL_N) are located in the memory cell array 11. M and N are positive integers.

Each memory cell MC is coupled to one word line WL and one bit line BL. Each memory cell MC includes one MTJ element MTJ and one switching element SE. In each memory cell MC, the MTJ element MTJ and the switching element SE are coupled in series. The switching element SE of each memory cell MC is coupled to one word line WL. The MTJ element MTJ of each memory cell MC is coupled to one bit line BL.

The MTJ element MTJ exhibits a tunnel magnetoresistive effect, and for example, is an element including a magnetic tunnel junction (MTJ). The MTJ element MTJ is also referred to a magnetoresistive effect element MTJ. The MTJ element MTJ is a variable resistance element that can switch between a low resistance state and a high resistance state. The MTJ element MTJ can store 1-bit data using a difference between the two resistance states. In one example, the MTJ element MTJ stores “0” data according to the low resistance state and “1” data according to the high resistance state.

The switching element SE is an element that has two terminals and performs electrical coupling or uncoupling between the two terminals. When a voltage applied between the two terminals in a first direction is lower than a certain threshold voltage, the switching element SE is in a high resistance state, for example, an electrically non-conductive state (or, OFF state). When the voltage applied between the two terminals rises to be equal to or higher than the threshold voltage, the switching element SE enters a low resistance state, for example, an electrically conductive state (or, ON state). When the voltage applied between the two terminals of the switching element SE in the low resistance state drops to be lower than the threshold voltage, the switching element SE enters the high resistance state. The switching element SE has, in a second direction opposite to the first direction, the same function as the function of switching between the high resistance state and the low resistance state based on the magnitude of the voltage applied in the first direction. That is, the switching element SE is a bidirectional switching element. By turning on or off the switching element SE, the presence or absence of supply of a current to the MTJ element MTJ coupled to the switching element SE, that is, selection or non-selection of the MTJ element MTJ can be controlled.

### 1.1.3. Structure of Memory Cell Array

FIG. 3 is a perspective view of a part of the memory cell array of the memory device of the first embodiment. As illustrated in FIG. 3, a plurality of conductors 21 and a plurality of conductors 22 are provided.

The conductors 21 each have a linear shape extending along an x axis. The conductors 21 are aligned along a y axis. The y axis is perpendicular to the x axis. Each of the conductors 21 functions as a single word line WL.

The conductors 22 are located above the conductors 21 on a z axis. The z axis is perpendicular to the x axis and the y axis. The conductors 22 each have a linear shape, extend along the y axis, and are aligned along the x axis. Each of the conductors 22 functions as a single bit line BL.

One memory cell MC is provided at each of intersections of the conductors 21 and the conductors 22. Each memory cell MC includes a structure functioning as the switching element SE and a structure functioning as the MTJ element MTJ. Each of the structure functioning as the switching element SE and the structure functioning as the MTJ element MTJ includes one or more layers. In one example, the structure functioning as the MTJ element MTJ is located on the upper surface of the structure functioning as the switching element SE. The lower surface of the memory cell MC is in contact with the upper surface of one conductor 21. The upper surface of the memory cell MC is in contact with the lower surface of one conductor 22.

### 1.1.4. Memory Cell

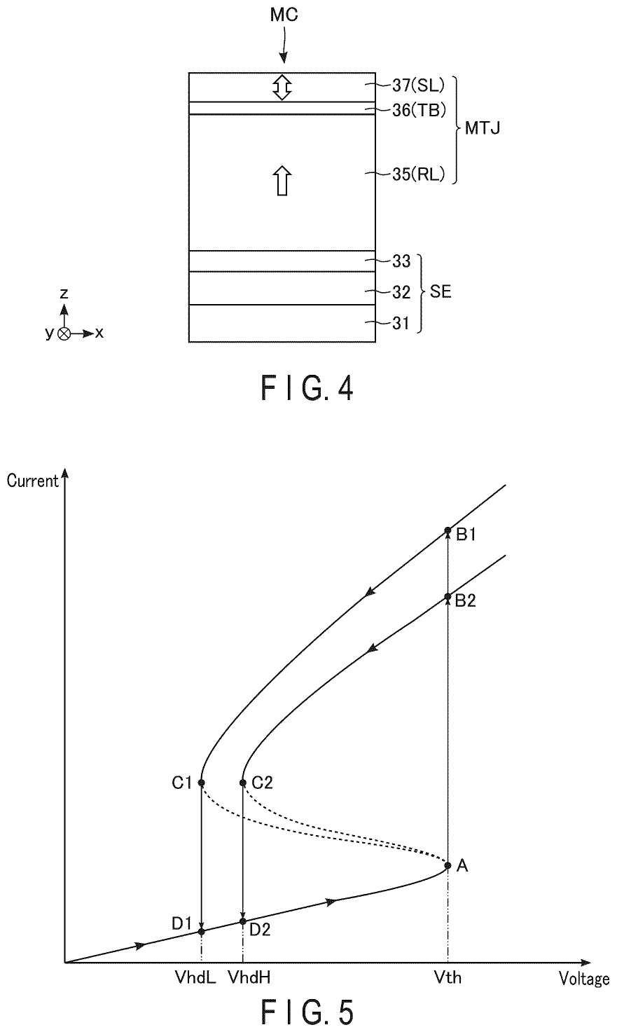

FIG. 4 illustrates a cross section of an example of the structure of the memory cell of the memory device of the first embodiment.

The switching element SE includes a variable resistance material 32. The variable resistance material 32 is a material exhibiting dynamically variable resistance, and, in one example, has a layer shape. The variable resistance material 32 is a switching element between its two terminals where a first terminal of the two terminals is one of the upper surface and the lower surface of the variable resistance material 32, and a second terminal of the two terminals is the other of the upper surface and the lower surface of the variable resistance material 32. When a voltage applied between the two terminals is lower than a certain threshold voltage, the variable resistance material 32 is in a “high resistance” state, for example, an electrically non-conductive state. When the voltage applied between the two terminals rises to be equal to or higher than the threshold voltage, the variable resistance material enters a “low resistance” state, for example, an electrically conductive state. When the voltage applied between the two terminals of the variable resistance material 32 in the low resistance state drops to be lower than the threshold voltage, the variable resistance material enters the high resistance state.

In one example, the variable resistance material 32 includes an insulator and a dopant introduced into the insulator by ion implantation. The insulator includes, for example, an oxide which may be SiO2, or a material consisting substantially of SiO2. In one example, the dopant includes arsenic (As) and germanium (Ge). The description “consisting (or formed) substantially of” and similar terms are meant to permit a component “consisting substantially of” something to contain unintended impurities.

The switching element SE can further include a lower electrode 31 and an upper electrode 33. FIG. 4 illustrates such an example. The variable resistance material 32 is located on the upper surface of the lower electrode 31, and the upper electrode 33 is located on the upper surface of the variable resistance material 32.

The MTJ element MTJ includes a ferromagnetic layer 35, an insulating layer 36, and a ferromagnetic layer 37. As an example, as illustrated in FIG. 4, the insulating layer 36 is located on the upper surface of the ferromagnetic layer 35, and the ferromagnetic layer 37 is located on the upper surface of the insulating layer 36.

The ferromagnetic layer 35 is a layer of a material exhibiting ferromagnetism. The ferromagnetic layer 35 has an axis of easy magnetization in a direction piercing through interfaces among the ferromagnetic layer 35, the insulating layer 36, and the ferromagnetic layer 37. A magnetization direction of the ferromagnetic layer 35 is intended to be unchanged even by reading and writing of data in the memory cell MC. The ferromagnetic layer 35 functions as a so-called reference layer. The ferromagnetic layer 35 may include a plurality of layers. Hereinafter, the ferromagnetic layer 35 may be referred to as reference layer RL.

The insulating layer 36 is a layer of an insulator. The insulating layer 36 includes or consists substantially of, for example, magnesium oxide (MgO) and functions as a so-called tunnel barrier (TB).

The ferromagnetic layer 37 is a layer of a material exhibiting ferromagnetism. The ferromagnetic layer 37 includes or consists substantially of, for example, cobalt iron boron (CoFeB) or iron boride (FeB). The ferromagnetic layer 37 has an axis of easy magnetization in a direction piercing through interfaces among the ferromagnetic layer 35, the insulating layer 36, and the ferromagnetic layer 37. A magnetization direction of the ferromagnetic layer 37 is variable by data writing to the memory cell MC, and the ferromagnetic layer 37 functions as a so-called storage layer (SL). Hereinafter, the ferromagnetic layer 37 may be referred to as storage layer SL.

When a magnetization direction of the storage layer SL is parallel to the magnetization direction of the reference layer RL, the MTJ element MTJ has certain low resistance. When the magnetization direction of the storage layer SL is antiparallel to the magnetization direction of the reference layer RL, the MTJ element MTJ has resistance higher than resistance in the case in which the magnetization direction of the storage layer SL and the magnetization direction of the reference layer RL are antiparallel.

When a current having magnitude equal to or larger than a current having a certain magnitude flows from the storage layer SL toward the reference layer RL, the magnetization direction of the storage layer SL becomes parallel to the magnetization direction of the reference layer RL. When a current having another magnitude flows from the reference layer RL toward the storage layer SL, the magnetization direction of the storage layer SL becomes antiparallel to the magnetization direction of the reference layer RL.

The MTJ element MTJ may include further layers.

FIG. 5 illustrates an example of curves of voltage and current characteristics of the memory cell of the memory device of the first embodiment. The horizontal axis of a graph indicates the magnitude of a terminal voltage (that is, a difference in potential between both terminals) of the memory cell MC. The vertical axis of the graph indicates, in a logarithmic scale, the magnitude of a current flowing through the memory cell MC. In FIG. 5, virtual characteristics that do not actually appear are indicated by broken lines. FIG. 5 illustrates a case in which the memory cell MC is in the low resistance state and a case in which the memory cell MC is in the high resistance state.

When the voltage is increased from 0, the current keeps increasing until reaching a threshold voltage Vth. Until the voltage reaches the threshold voltage Vth, the switching element SE of the memory cell MC is off, that is, is non-conductive.

When the voltage is further increased and the voltage reaches the threshold voltage Vth, that is, reaches a point A, a relation between the voltage and the current shows a discontinuous change and shows characteristics shown at points B1 and B2. The magnitude of the current at the points B1 and B2 is greatly larger than the magnitude of the current at the point A. This rapid change in the current is based on the switching element SE of the memory cell MC being turned on. The magnitude of the current at the points B1 and B2 depends on a resistance state of the MTJ element MTJ of the memory cell MC.

When the voltage is reduced from the state in which the switching element SE is on, for example, a state in which the voltage and the current indicate a relation shown at the point B1 or B2 and points having a higher voltage than the point B1 or B2, the current keeps decreasing.

When the voltage is further reduced and reaches a certain magnitude, the relation between the voltage and the current shows a discontinuous change. The voltage when the relation between the voltage and the current starts to show discontinuity depends on the terminal voltage of the MTJ element MTJ of the memory cell MC, that is, depends on whether the MTJ element MTJ is in the high resistance state or the low resistance state. When the MTJ element MTJ is in the low resistance state, the relation between the voltage and the current shows discontinuity from a point C1. When the MTJ element MTJ is in the high resistance state, the relation between the voltage and the current shows discontinuity from a point C2. When the voltage reaches the points C1 and C2, the relation between the voltage and the current shows characteristics shown at points D1 and D2. The magnitudes of the currents at the points D1 and D2 are respectively greatly smaller than the magnitudes of the currents at the points C1 and C2. This rapid change in the current is based on the switching element SE of the memory cell MC being turned off.

The terminal voltage at the point D1 of the memory cell MC including the MTJ element MTJ in the low resistance state is referred to as low hold voltage VhdL. The terminal voltage at the point D2 of the memory cell MC including the MTJ element MTJ in the high resistance state is referred to as high hold voltage VhdH.

### 1.1.5. Read Circuit

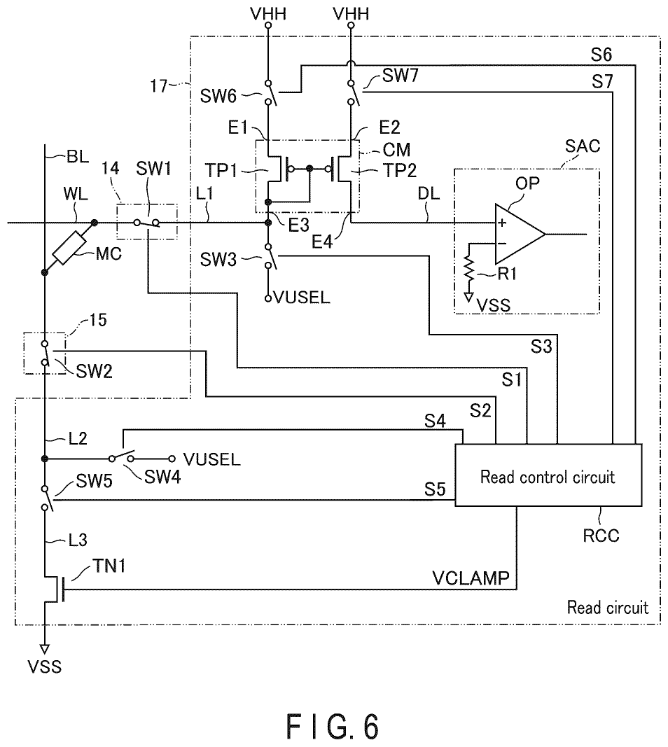

FIG. 6 illustrates an example of components and coupling of the components of the read circuit of the memory device of the first embodiment. FIG. 6 illustrates, as a representative, a state in which a certain memory cell MC is selected as well as a sense amplifier circuit SAC. That is, as described above with reference to FIG. 1, one word line WL is selected by the row selection circuit 14, and one bit line BL is selected by the column selection circuit 15. One memory cell MC coupled to one word line WL in the selected state and one bit line BL in the selected state is in a selected state, and data is read from the memory cell MC in the selected state. Then, the word line WL, the bit line BL, and the memory cell MC illustrated in FIG. 6 are in a selected state. Hereinafter, the word line WL in the selected state may be referred to as a selected word line WL. The bit line BL in the selected state may be referred to as a selected bit line BL. The memory cell MC in the selected state may be referred to as a selected memory cell MC.

As illustrated in FIG. 6, the read circuit 17 is coupled to the word line WL via the switch SW1 that is on in the row selection circuit 14. In one example, the switch SW1 is a p-type or n-type metal oxide semiconductor field effect transistor (MOSFET). Alternatively, the switch SW1 is a set of a p-type MOSFET and an n-type MOSFET that are coupled in parallel and receive signals of logic opposite to each other (or complementary) at respective gates of the MOSFETs. The switch SW1 receives the signal S1. While receiving the signal S1 at a high (or, “H”) level, the switch SW1 remains on and maintains a state in which one terminal and the other terminal of the switch SW1 are electrically coupled. While receiving the signal S1 at a low (or, “L”) level, the switch SW1 remains off and maintains a state in which one terminal and the other terminal of the switch SW1 are electrically uncoupled.

The same applies to a switch SWn and a signal Sn described below, where n is an integer of 2 or more. That is, a description in which the description about the switch SW1 is replaced with the switch SWn applies to the switch SWn, and a description in which the description about the signal S1 is replaced with the signal Sn applies to the signal Sn.

The read circuit 17 is coupled to the bit line BL via the switch SW2 that is on in the column selection circuit 15.

The read circuit 17 includes the sense amplifier circuit SAC, switches SW3 to SW5, a current mirror circuit CM, an n-type MOSFET (transistor) TN1, interconnects L1 to L3 and DL, and a control circuit RCC.

The interconnects L1 is coupled to one terminal of the switch SW1. The SW1 is coupled to, at the other terminal, the word line WL.

The interconnects L2 is coupled to one terminal of the switch SW2. The switch SW2 is coupled to, at the other and, the bit line BL.

The switch SW3 is coupled between the interconnect L1 and a node configured to receive a non-selected voltage VUSEL. The node configured to receive the non-selected voltage VUSEL functions as a node configured to supply the non-selected voltage VUSEL. In one example, the non-selected voltage VUSEL is supplied from the voltage generator 18. In one example, the non-selected voltage VUSEL has a certain magnitude. The non-selected voltage VUSEL has a magnitude ranging between a magnitude of a ground voltage VSS and a magnitude of a voltage VHH. The voltage VHH is an internal power-supply voltage and has a positive magnitude. In one example, the non-selected voltage VUSEL is half the magnitude of the voltage VHH. In one example, the voltage VHH is supplied from the voltage generator 18.

The switch SW4 is coupled between the interconnect L2 and a node configured to receive the non-selected voltage VUSEL.

The switch SW5 is coupled between the interconnect L2 and the interconnect L3.

The transistor TN1 is coupled between the interconnect L3 and the ground voltage VSS. The transistor TN1 receives, at its gate, a voltage VCLAMP. The voltage CLAMP has a certain magnitude. The interconnect L3 receives the voltage VCLAMP via the transistor TN1.

The current mirror circuit CM includes terminals E1, E2, E3, and E4. The current mirror circuit CM receives a current at its terminals E1 and E2 and receives a voltage.

The current mirror circuit CM outputs a current at its terminal E3. A current flowing through the terminal E3 functions as a reference current of the current mirror circuit CM. The terminal E3 is coupled to the interconnect L1.

The current mirror circuit CM outputs an output current at its terminal E4. Based on the reference current, the output current is substantially equal in magnitude to the reference current. The expression “substantially equal (identical)” used herein and the claims intends to indicate that two or more components which are “substantially equal (identical)” are identical, but are not completely identical due to limitations in manufacturing technology and/or measuring technology. The terminal E4 is coupled to the interconnect DL.

In one example, the current mirror circuit CM includes p-type MOSFETs (transistors) TP1 and TP2. The transistor TP1 is coupled between the terminal E1 and the terminal E3 and is coupled at its gate to the interconnect L1.

The transistor TP2 is coupled between the terminal E2 and the terminal E4 and is coupled at its gate to a gate of the interconnect L1 and the transistor TP1. In one example, while the transistors TP1 and TP2 receive terminal voltages equal in magnitude and voltages equal in magnitude at their gates, substantially identical drain currents flow through the transistors TP1 and TP2. In one example, the transistor TP2 is substantially equal in characteristics to the transistor TP1. Examples of characteristics include a gate width of a transistor and a gate length of the transistor.

The switch SW6 is coupled between a node configured to receive the voltage VHH and the terminal E1. The node configured to receive the voltage VHH functions as a node configured to supply the voltage VHH.

The switch SW7 is coupled between the node configured to receive the voltage VHH and the terminal E2.

The sense amplifier circuit SAC is a circuit configured to output data determined to be stored in a corresponding memory cell MC targeted for data reading, by using a voltage based on the data stored in the memory cell MC targeted for data reading. In one example, the sense amplifier circuit SAC includes an operational amplifier OP and a resistor R1. A non-inversion input of the operational amplifier OP is coupled to the interconnect DL. An inversion input of the operational amplifier OP is coupled to one terminal of the resistor R1. The other terminal of the resistor R1 is coupled to a node of the ground voltage VSS. In one example, the inversion input of the operational amplifier OP has a potential of a magnitude ranging between a magnitude of the high hold voltage VhdH and the low hold voltage VhdL. The resistor R1 has a magnitude such that the inversion input of the operational amplifier OP can have such a potential.

The read control circuit RCC outputs signals S1 to S7.

### 1.2. Operation

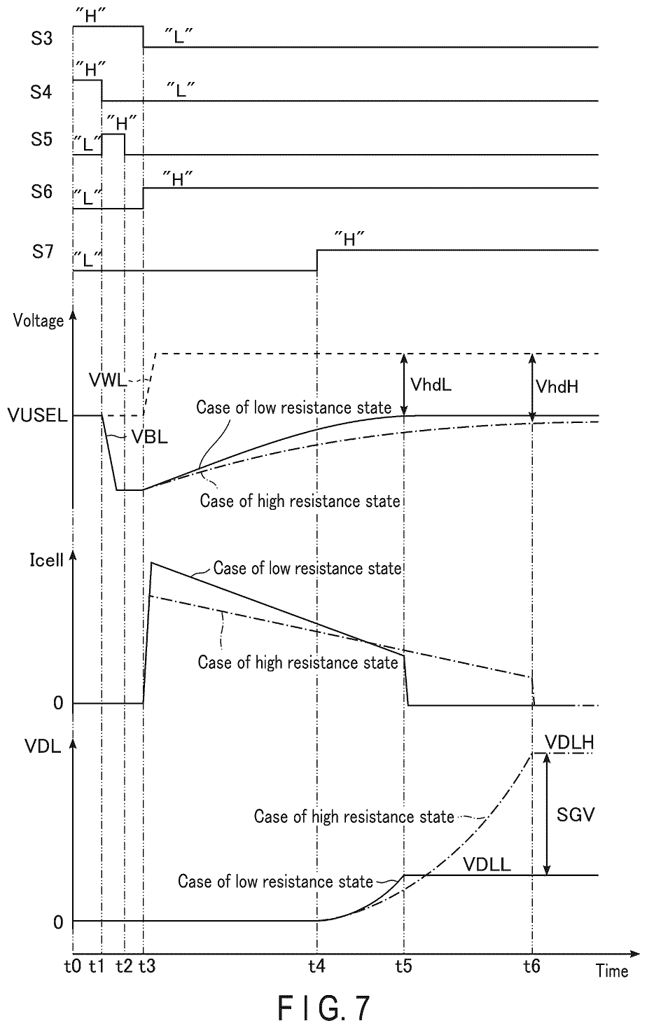

FIG. 7 illustrates states of several signals during data reading of the memory device of the first embodiment along time. FIG. 7 illustrates states in which a single memory cell MC targeted for data reading is selected as illustrated in FIG. 6. That is, for a period illustrated in FIG. 7, both of the switches SW1 and SW2 coupled to the selected memory cell MC illustrated in FIG. 6 remain on. Furthermore, the word line WL and the bit line illustrated in FIG. 6 respectively correspond to the selected word line WL and the selected bit line BL. The operation during a period illustrated in FIG. 7 starts when data reading starts in a state in which a memory cell MC targeted for data reading is selected.

At time to, signals, voltages of nodes, and a current are in states described below. The signals S3 and S4 are each at a high level, and the signals S5, S6, and S7 are each at a low level. Accordingly, the switches SW3 and SW4 are on, and the switches SW4, SW5, and SW7 are off.

Based on the switches SW6 and SW7 being off and the switch SW3 being on, the selected word line WL receives the non-selected voltage VUSEL. Thus, a selected word line potential VWL has a non-selected potential VUSEL. The selected word line potential VWL is a potential of the selected word line WL. The non-selected potential VUSEL is a potential having a magnitude that an interconnect has while receiving the non-selected voltage VUSEL. In one example, the non-selected potential VUSEL is substantially equal in magnitude to the non-selected voltage VUSEL. By the selected word line WL having the non-selected voltage VUSEL, the transistors TP1 and TP2 are on.

Based on the switch SW5 being off and the switch SW4 being on, the selected word line BL receives the non-selected voltage VUSEL. Thus, a selected bit line potential VBL has the non-selected potential VUSEL. The selected word line potential VBL is a potential of the selected bit line BL.

The selected word line WL and the selected bit line BL have the non-selected potential VUSEL, so that a terminal voltage of the switching element SE of the selected memory cell MC is lower than the threshold voltage Vth. Thus, the switching element SE of the selected memory cell MC is off. Therefore, a cell current Icell does not flow. The cell current Icell is a current that flows through the selected memory cell MC.

At time t1, the signal S4 is set to a low level and the signal S5 is set to a high level. This turns on the switch SW4 and turns off the switch SW5. Accordingly, the selected bit line BL stops receiving the non-selected voltage VUSEL while starting receiving a voltage that the interconnect L3 is receiving, that is, the voltage VCLAMP. The voltage VCLAMP is lower than the non-selected voltage VUSEL. Thus, the selected bit line BL is precharged to a potential lower than the non-selected voltage VUSEL.

At time t2, the signal S5 is set to the low level. This turns off the switch SW5 and brings the selected bit line BL into an electrically floating state.

At time t3, the signal S3 is set to the low level and the signal S6 is set to the high level. This turns off the switch SW3 and turns on the switch SW6. Accordingly, the selected word line WL stops receiving the non-selected voltage VUSEL while starting receiving the voltage VHH. This causes the current to flow through the transistor TP1. By this, the selected word line potential VWL is precharged to the potential VHH. A potential VHH is substantially equal in magnitude to the voltage VHH.

In response to the selected word line potential VWL rising and a difference between the selected word line potential VWL and the selected word line potential VBL reaching the threshold voltage Vth, the switching element SE of the selected memory cell MC is turned on. By this, the cell current Icell starts to flow from the selected word line WL toward the selected bit line BL. The cell current Icell rises sharply from time t3, thereby reaching a magnitude of a certain peak. The current that flows through the transistor TP1 after the switching element SE of the selected memory cell MC is turned on is substantially equal to the cell current Icell.

A magnitude of a peak of the cell current Icell depends on whether the MTJ element MTJ of the selected memory cell MC is in a low resistance state or a high resistance state. A peak of the cell current Icell in a case in which the MTJ element MTJ of the selected memory cell MC is in the low resistance state is larger in magnitude than a peak of the cell current Icell in a case in which the MTJ element MTJ of the selected memory cell MC is in the high resistance state.

The cell current Icell charges the selected bit line BL. Accordingly, the selected bit line potential VBL rises from time t3. A rising speed of the selected bit line potential VBL depends on whether the MTJ element MTJ of the selected memory cell MC is in the low resistance state or the high resistance state. The selected bit line potential VBL in a case in which the MTJ element MTJ of the selected memory cell MC is in the low resistance state rises faster than the selected bit line potential VBL in a case in which the MTJ element MTJ of the selected memory cell MC is in the high resistance state.

The cell current Icell reaches its peak immediately after time t3, and drops thereafter. A dropping speed of the cell current Icell depends on whether the MTJ element MTJ of the selected memory cell MC is in the low resistance state or the high resistance state. The cell current Icell in a case in which the MTJ element MTJ of the selected memory cell MC is in the low resistance state drops faster than the cell current Icell in a case in which the MTJ element MTJ of the selected memory cell MC is in the high resistance state. This is because the selected bit line potential VBL in a case in which the MTJ element MTJ of the selected memory cell MC is in the low resistance state rises faster than the selected bit line potential VBL in a case in which the MTJ element MTJ of the selected memory cell MC is in the high resistance state.

At time t4, the signal S7 is set to the high level. This turns on the switch SW7. Accordingly, a current (that is, the cell current Icell) substantially equal in magnitude to a current (that is, the cell current Icell) flowing through the transistor TP1 flows through the transistor TP2. The cell current Icell flowing through the transistor TP2 charges the interconnect DL and causes a potential VDL to rise. The potential VDL is a potential of the interconnect DL.

A rising speed of the potential VDL depends on whether the MTJ element MTJ of the selected memory cell MC is in the low resistance state or the high resistance state. The potential VDL in a case in which the MTJ element MTJ of the selected memory cell MC is in the low resistance state rises faster than the potential VDL in a case in which the MTJ element MTJ of the selected memory cell MC is in the high resistance state.

In a case where the MTJ element MTJ of the selected memory cell MC is in the low resistance state at time t5, a difference between the selected bit line potential VBL and the selected word line potential VWL, each of which continues to rise from t3, reaches the low hold voltage VhdL. This turns off the switching element SE of the selected memory cell MC and sets the cell current Icell to zero. By the cell current Icell being set to zero, charging of the interconnect DL stops. As a result, the potential VDL becomes a potential VDLL of a certain magnitude.

In a case where the MTJ element MTJ of the selected memory cell MC is in the high resistance state at time t6, a difference between the selected bit line potential VBL and the selected word line potential VWL, each of which continues to rise from t3, reaches the high hold voltage VhdH. This turns off the switching element SE of the selected memory cell MC and sets the cell current Icell to zero. By the cell current Icell being set to zero, charging of the interconnect DL stops. As a result, the potential VDL becomes a potential VDLH of a certain magnitude. The potential VDLH is higher than the voltage VDL by a difference SGV.

After t6, data which is determined based on the voltage VDL and is determined to be stored in the selected memory cell MC is output from the sense amplifier circuit SAC. In one example, in a case where the voltage VDL is equal to the voltage VDLL, that is, a case where a difference between the selected word line potential VWL and the selected bit line potential VBL is equal to the low hold voltage VhdL, the sense amplifier circuit SAC outputs a signal at a low level. In a case where the voltage VDL is equal to the voltage VDLH, that is, a case where a difference between the selected word line potential VWL and the selected bit line potential VBL is equal to the high hold voltage VhdH, the sense amplifier circuit SAC outputs a signal at a high level.

### 1.3. Advantages (Advantageous Effects)

According to the first embodiment, it is possible to provide a memory device capable of ensuring a large signal difference and accurately reading data under easy control, as will be described below.

Data can be read from the memory cell MC using a voltage. In such a case, the selected word line WL is coupled to the sense amplifier circuit SAC. The selected word line WL is precharged upon application of a voltage higher than the non-selected voltage VUSEL and is then brought into an electrically floating state. Thereafter, a voltage lower than the non-selected voltage VUSEL is continuously applied to the selected word line BL. As a result, the selected word line potential VWL drops, and when a difference between the selected word line potential VWL and the selected bit line potential VBL becomes equal to the low hold voltage VhdL or the high hold voltage VhdH, the switching element SE is turned off, so that dropping of the selected word line potential VWL stops. The selected word line potential VWL at the time when dropping stops is used as a signal, and a difference from the selected word line potential VWL in cases of the low resistance state and the high resistance state corresponds to a signal difference. However, a timing at which the switching element SE is turned off, in particular in a case of the high resistance state, is later than expected. Thus, the selected word line potential VWL is low after the switching element SE in a case of the high resistance state is turned off. As a result, a signal difference is small.

To address this, one option is to stop application of a voltage to the selected bit line BL. By doing so, the switching element SE is turned off before it is automatically turned off in response to a voltage reaching a hold voltage (the low hold voltage VhdL or the high hold voltage VhdH). Thus, the selected word line potential VWL after the switching element SE in a case of the high resistance state is turned off is high, thereby achieving a larger signal difference. However, there may be a variation in the voltages (clamp voltages) received by gates of transistors for precharging selected word lines WL, which may cause variation in the potentials of the precharged selected word lines WL. In a case where the switching element SE is automatically turned off in response to a voltage reaching the hold voltage, a variation in the clamp voltages does not influence a timing at which the switching element SE is turned off because turning-off of the switching element SE irrespective of the clamp voltage depends on the hold voltage. On the other hand, if the switching element SE is turned off in response to application of a voltage to the selected word line BL being stopped, a variation in the clamp voltages influence the selected word line potential VWL at a time when the switching element SE is turned off. It is difficult to determine an appropriate timing of application of a voltage to the selected bit line BL in consideration of the above matter and an inevitable characteristic variation in the characteristics of the memory cell MC.

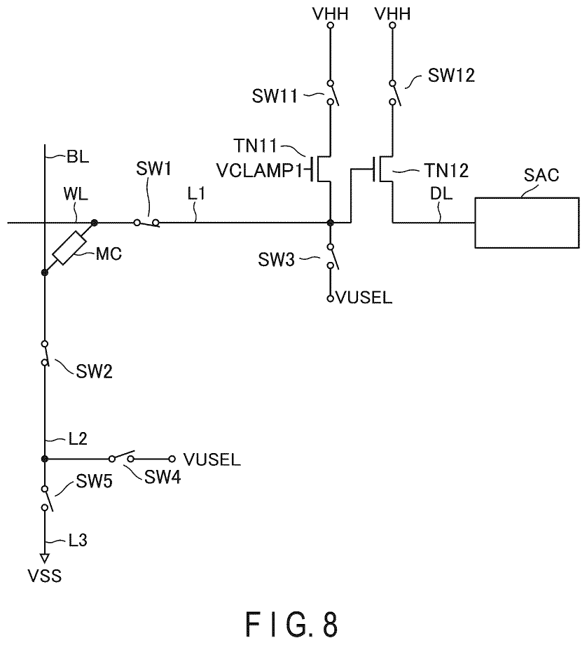

On the other hand, data may be read using a current in order to obtain a large signal difference. In such a case, as shown in FIG. 8, the word line WL is coupled to a gate of the transistor TN12 coupled between a node that receives the voltage VHH and the sense amplifier circuit SAC, unlike the word line WL being coupled to the sense amplifier circuit SAC in a case of using a voltage. In order to charge the interconnect DL coupled to the sense amplifier circuit SAC with the cell current Icell, the switch SW12 is turned on concurrently with the start of precharging of the selected bit line BL. Therefore, a current continuously flows through the transistor TN12 after the start of precharging of the selected bit line BL. This results in large power consumption.

The memory device 1 according to the first embodiment includes the current mirror circuit CM configured to use the cell current Icell as a reference current and to supply an output current copied from the reference current to the interconnect DL coupled to the sense amplifier circuit SAC. Thus, a voltage received by the sense amplifier circuit SAC is formed by an integration of a copied current based on a current copied from the cell current Icell. Therefore, even with a small copied current, the potential VDL increases in a short time. Thus, a large signal difference SVG can be obtained. This makes it possible to realize a high margin in data reading and to realize high data reading performance.

Furthermore, stopping of an output current in a case of the MTJ element MTJ being at the low resistance state and stopping of an output current in a case of the MTJ element MTG being at the high resistance state automatically occur depending on a resistance state of the MTJ element MTJ. This eliminates the need to control stopping of an output current and suppresses the need to ensure a margin for a timing of controlling stopping of the output current to address an inevitable variation in the characteristics of the memory cells MC and/or misreading of data due to lack of a margin. Rather, a large difference between the potential VDLL and the potential VDLH, that is, a large signal difference SGV, can be obtained by charging of the interconnect DL in a period (from time t5 to time t6 in FIG. 7) during which a current flows only in a case of the high resistance state by utilizing an output current stopping based on a resistance state of the MTJ element MTJ. Accordingly, the memory device 1 that realizes easy control and accurate reading of data is provided.

Furthermore, because of the use of the current mirror circuit CM, not the cell current Icell but an output current copied from the cell current Icell forms the potential VDL. Therefore, the start of output of the output current of the current mirror circuit CM can be delayed after the start of data reading. Therefore, a current for charging the interconnect DL does not need to continuously flow from the start of data reading. Accordingly, the memory device 1 that is small in power consumption is provided.

Meanwhile, control of output of the output current, that is, turning-on of the switch SW7, needs to be controlled. Therefore, the need for control to ensure a margin for a timing at which the switch SW7 is turned on may complicate control of the memory device 1. However, as described above, a potential of the interconnect DL is generated by an integration over a longer period in a case of the MTJ element MTJ in the high resistance state than in the case of the MTJ element MTJ in the low resistance state. Thus, the large signal difference SVG is easily obtained. For this reason, the large signal difference SVG can be ensured even if there is a variation in the timings at which the switch SW7 is turned on. This facilitates control.

Therefore, in the configuration shown in FIG. 8, a precharge circuit (that is, the transistor TN11 and an interconnect for transmitting a clamp voltage VCLAMP1) for the word line WL is located in the vicinity of the sense amplifier circuit SAC, whereas in the first embodiment, the precharge circuit (that is, the transistor TN1 and an interconnect for transmitting the voltage VCLAMP) is coupled to the bit line BL and does not need to be located in the vicinity of the sense amplifier circuit SAC. An interconnect in which a potential fluctuates frequently is arranged in the sense amplifier circuit SAC and its vicinity. Therefore, in a case where the precharge circuit is arranged in the vicinity of the sense amplifier circuit SCA, the precharge circuit is prone to be influenced. According to the first embodiment, the transistor TN1 can be arranged away from the sense amplifier, which can alleviate the influence.

### 1.4. Modification

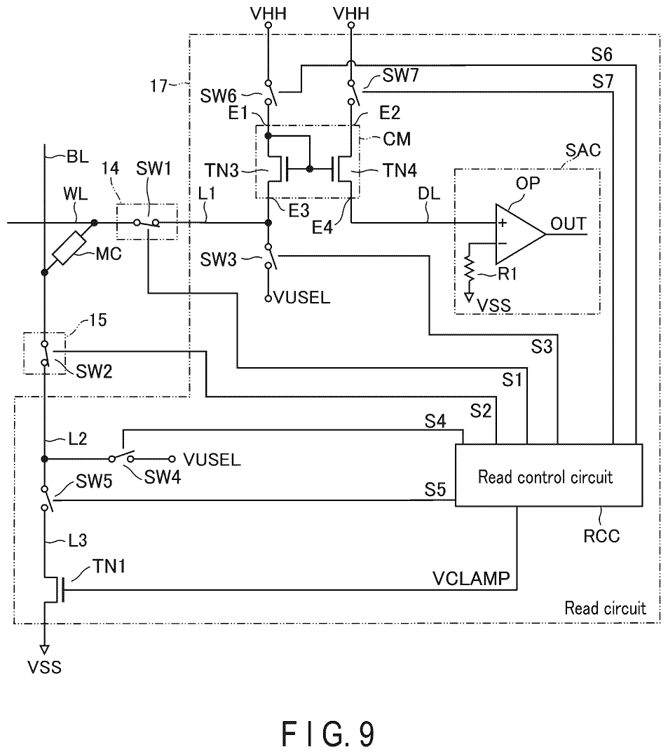

The current mirror circuit CM may be constituted by n-type MOSFETs. FIG. 9 shows such an example and illustrates components of a memory device and coupling of the components of a modification of the first embodiment. As shown in FIG. 9, the current mirror circuit CM of the memory device 1 according to the modification includes transistors TN3 and TN4 instead of the transistors TP1 and TP2, respectively. A gate of the transistor TN3 is coupled to a drain of the transistor TN3. In one example, while the transistors TN3 and TN4 receive terminal voltages equal in magnitude and voltages equal in magnitude at their gates, substantially identical drain currents flow through the transistors TN3 and TN4. In one example, the transistor TN4 has characteristics substantially equal to those of the transistor TN3. Examples of characteristics include a gate width of a transistor and a gate length of the transistor. Use of the transistors TN3 and TN4 also produce the same advantageous effects as those produced by use of the transistors TP1 and TP2.

The transistor TP1 and the transistor TP2 may have characteristics that result in different drain currents flowing while receiving terminal voltages equal in magnitude and voltages equal in magnitude at their gates. In one example, the transistor TP2 causes a drain current larger than that of the transistor TP1 to flow while the transistors TP1 and TP2 receive terminal voltages equal in magnitude and voltages equal in magnitude. In one example, the transistor TP2 has a gate width larger than that of the transistor TP1 or/and has a gate length smaller than that of the transistor TP1. In one example, the transistor TP2 has an n-fold gate width of that of the transistor TP1 or/and an n-fold gate length of that of the transistor TP1. Herein, n is a number larger than 1. In this manner, charging of the interconnect DL is accelerated and a larger signal difference SGV can be obtained. In a case where the current mirror circuit CM is constituted by the transistors TN3 and TN4, the transistors TN3 and TN4 may have the same relation as that of the transistors TP1 and TP2.

The memory cell MC may include any variable resistance element in lieu of the MTJ element MTJ. The variable resistance element is, similar to the MTJ element MTJ, an element capable of dynamically switching between two resistance states. The variable resistance element switches between the two resistance states according to the current flowing through the variable resistance element and/or the voltage applied to the variable resistance element.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a memory cell including a first terminal and a second terminal;
a first interconnect coupled to the first terminal;
a second interconnect coupled to the second terminal;
a first switch coupled between the second interconnect and a third interconnect configured to be coupled to a first voltage;
a current mirror circuit including a third terminal and a fourth terminal, coupled to the first interconnect at the third terminal, and configured to output an output current using a first current flowing through the first interconnect as a reference current at the fourth terminal; and
a sense amplifier circuit coupled to the fourth terminal.

2. The memory device according to claim 1, wherein
the current mirror circuit further includes a fifth terminal configured to be coupled to a second voltage higher than the first voltage, and a sixth terminal configured to be coupled to the second voltage.

3. The memory device according to claim 2, further comprising:
a second switch coupled between the second node and the fifth terminal, and
a third switch coupled between the second node and the sixth terminal.

4. The memory device according to claim 3, wherein
the second switch and the third switch are turned on at different timings.

5. The memory device according to claim 4, further comprising:
a fourth switch coupled to a node set to a third voltage between a ground voltage and the second voltage; and
a fifth switch coupled between the second interconnect and the node set to the third voltage.

6. The memory device according to claim 5, wherein
the fourth switch and the fifth switch are turned on,
the fifth switch is turned off, and is turned on after the first switch is turned on,
the fourth switch is turned off and the second switch is turned on after the first switch is turned off, and
the third switch is turned on after the second switch is turned on.

7. The memory device according to claim 6, wherein
the third switch is maintained off until the third switch is turned on while the second switch is on.

8. The memory device according to claim 1, wherein
the current mirror circuit outputs the output current different in magnitude from the first current.

9. The memory device according to claim 1, wherein
the memory cell includes a variable resistance material, and
the variable resistance material includes a seventh terminal and an eighth terminal, has a first resistance between the seventh terminal and the eighth terminal upon application of a positive fourth voltage from the seventh terminal toward the eighth terminal, has a second resistance lower than the first resistance between the seventh terminal and the eighth terminal upon application of a positive fifth voltage lower than the fourth voltage from the seventh terminal toward the eighth terminal, has a third resistance between the seventh terminal and the eighth terminal upon application of a positive sixth voltage from the eighth terminal toward the seventh terminal, and has a fourth resistance lower than the third resistance between the seventh terminal and the eighth terminal upon application of a positive seventh voltage lower than the sixth voltage from the eighth terminal toward the seventh terminal.

10. The memory device according to claim 9, wherein
the memory cell further includes:
a first ferromagnetic layer;
a second ferromagnetic layer; and
an insulating layer between the first ferromagnetic layer and the second ferromagnetic layer.

11. The memory device according to claim 2, wherein
the current mirror circuit includes a first p-type transistor and a second p-type transistor,
the first p-type transistor is coupled between the fifth terminal and the third terminal, and includes a first gate coupled to the third terminal, and
the second p-type transistor is coupled between the sixth terminal and the fourth terminal, and includes a second gate coupled to the first gate.

12. The memory device according to claim 11, wherein
the second p-type transistor is different in gate length or gate width from the first p-type transistor.

13. The memory device according to claim 11, wherein
the memory cell includes a variable resistance material, and
the variable resistance material includes a seventh terminal and an eighth terminal, has a first resistance between the seventh terminal and the eighth terminal upon application of a positive fourth voltage from the seventh terminal toward the eighth terminal, has a second resistance lower than the first resistance between the seventh terminal and the eighth terminal upon application of a positive fifth voltage lower than the fourth voltage from the seventh terminal toward the eighth terminal, has a third resistance between the seventh terminal and the eighth terminal upon application of a positive sixth voltage from the eighth terminal toward the seventh terminal, and has a fourth resistance lower than the third resistance between the seventh terminal and the eighth terminal upon application of a positive seventh voltage lower than the sixth voltage from the eighth terminal toward the seventh terminal.

14. The memory device according to claim 13, wherein
the memory cell further includes:
a first ferromagnetic layer;
a second ferromagnetic layer; and
an insulating layer between the first ferromagnetic layer and the second ferromagnetic layer.

15. The memory device according to claim 2, wherein
the current mirror circuit includes a first n-type transistor and a second n-type transistor,
the first n-type transistor is coupled between the fifth terminal and the third terminal, and includes a first gate coupled to the third terminal, and
the second n-type transistor is coupled between the sixth terminal and the fourth terminal, and includes a second gate coupled to the first gate.

16. The memory device according to claim 15, wherein
the second n-type transistor is different in gate length or gate width from the first n-type transistor.

17. The memory device according to claim 15, wherein
the memory cell includes a variable resistance material, and
the variable resistance material includes a seventh terminal and an eighth terminal, has a first resistance between the seventh terminal and the eighth terminal upon application of a positive fourth voltage from the seventh terminal toward the eighth terminal, has a second resistance lower than the first resistance between the seventh terminal and the eighth terminal upon application of a positive fifth voltage lower than the fourth voltage from the seventh terminal toward the eighth terminal, has a third resistance between the seventh terminal and the eighth terminal upon application of a positive sixth voltage from the eighth terminal toward the seventh terminal, and has a fourth resistance lower than the third resistance between the seventh terminal and the eighth terminal upon application of a positive seventh voltage lower than the sixth voltage from the eighth terminal toward the seventh terminal.

18. The memory device according to claim 17, wherein
the memory cell further includes:
a first ferromagnetic layer;
a second ferromagnetic layer; and
an insulating layer between the first ferromagnetic layer and the second ferromagnetic layer.

19. The memory device according to claim 4, further comprising:
a fourth switch coupled to a node set to a third voltage between a voltage at the third interconnect configured to be formed to apply the first voltage to the third interconnect and the second voltage; and
a fifth switch coupled between the second interconnect and the node set to the third voltage.

20. The memory device according to claim 19, wherein
the fourth switch and the fifth switch are turned on,
the fifth switch is turned off, and is turned on after the first switch is turned on,
the fourth switch is turned off and the second switch is turned on after the first switch is turned off, and
the third switch is turned on after the second switch is turned on.

21. The memory device according to claim 20, wherein
the third switch is maintained off until the third switch is turned on while the second switch is on.
